(19) United States
(12) Patent Application Publication
(10) Pub. No.: US 2025/0331351 A1
(43) Pub. Date: Oct. 23, 2025

(54) SUBSTRATE MODULE, METHOD FOR MANUFACTURING SUBSTRATE MODULE, AND DISPLAY MODULE

(71) Applicant: FOSHAN NATIONSTAR OPTOELECTRONICS CO., LTD., Foshan (CN)

(72) Inventors: Kuai QIN, Foshan (CN); Shaojia XIE, Foshan (CN); Caineng HUO, Foshan (CN); Bin CAI, Foshan (CN); Feng GU, Foshan (CN); Fangping HE, Foshan (CN)

(21) Appl. No.: 18/866,437

(22) PCT Filed: Dec. 14, 2022
(86) PCT No.: PCT/CN2022/139051

§ 371 Date: Nov. 15, 2024

(30) Foreign Application Priority Data
May 17, 2022 (CN) 202210539300.1

(51) Int. Cl. H10H 29/49; H10H 29/01

(52) U.S. Cl. CPC H10H 29/49; H10H 29/012

(57) ABSTRACT

A substrate module includes a first substrate on which pad groups and a test terminal are disposed; a driver chip disposed on a side of the first substrate facing away from the pad groups and the test terminal, where the driver chip is connected to the pad groups and the test terminal separately; a second substrate disposed on a side of the driver chip facing away from the first substrate, where pins are disposed on a side of the second substrate facing away from the first substrate, and the driver chip is connected to the pins; and a filling layer disposed between the first substrate and the second substrate and configured to enclose the driver chip.

This application claims priority to Chinese Patent Application No. 202210539300.1 filed with the China National Intellectual Property Administration (CNIPA) on May 17, 2022, the disclosure of which is incorporated herein by reference in its entirety.

### TECHNICAL FIELD

Embodiments of the present application relate to the field of display technology, for example, a substrate module, a method for manufacturing the substrate module, and a display module.

### BACKGROUND

As a new display technology, light-emitting diode (LED) displays are widely popular with users due to the advantages of energy saving, environmental friendliness, and high efficiency. An LED display in the related art generally includes a circuit board and a display module, where the display module includes light-emitting chips arranged in an array. To drive the light-emitting chips in the display module to emit light, multiple driver chips are typically disposed on the circuit board. However, the arrangement of the driver chips results in a large number of layers and a complex structure of the circuit board. To solve the problems of a large number of layers and a complex structure of the circuit board, the driver chips may be disposed on the front surface of the display module in the related art. However, the driver chips occupy a certain area of the display module and thus, the area of the display module for placing the light-emitting chips is reduced, lowering the pixel density of the display module.

### SUMMARY

The present application provides a substrate module, a method for manufacturing the substrate module, and a display module, so as to increase the pixel density of the display module and reduce the production cost of the display module.

In a first aspect, embodiments of the present application provide a substrate module. The substrate module includes a first substrate on which pad groups and a test terminal are disposed; a driver chip disposed on a side of the first substrate facing away from the pad groups and the test terminal, where the driver chip is connected to the pad groups and the test terminal separately; a second substrate disposed on a side of the driver chip facing away from the first substrate, where pins are disposed on a side of the second substrate facing away from the first substrate, and the driver chip is connected to the pins; and a filling layer disposed between the first substrate and the second substrate and configured to enclose the driver chip.

Optionally, the first substrate and the second substrate are each provided with connection lines and conductive vias, and the driver chip is connected to the pad groups, the test terminal, and the pins separately through connection lines and conductive vias.

Optionally, the first substrate is provided with first conductive vias and first connection lines, the second substrate is provided with second conductive vias and second connection lines, and each of the pad groups includes a first electrode pad and a second electrode pad; the driver chip is connected to the test terminal through a first conductive via and a first connection line, and the driver chip is connected to a first electrode pad through a first conductive via and a first connection line; the driver chip is connected to a second electrode pad through a first conductive via, a first connection line, and a second connection line; and the driver chip is connected to a pin through at least one of the first connection lines and the first conductive vias, and at least one of the second connection lines and the second conductive vias.

Optionally, the first connection lines include a first connection subline and a second connection subline, the first connection subline is disposed on a side of the first substrate facing the driver chip, and the second connection subline is disposed on a side of the first substrate facing away from the driver chip; a vertical projection of a part of the first conductive vias in a thickness direction of the first substrate at least partially overlaps a vertical projection of first electrode pads and second electrode pads corresponding to the part of the first conductive vias in the thickness direction of the first substrate; the driver chip is connected to a first electrode pad through a first conductive via and a first connection subline, and the driver chip is connected to a second electrode pad through a first conductive via, a first connection subline, and a second connection line; and the driver chip is connected to the test terminal through a first conductive via and at least one of the first connection subline and the second connection subline.

Optionally, the second connection lines are disposed on a side of the second substrate facing the driver chip, and a vertical projection of the second conductive vias in a thickness direction of the second substrate at least partially overlaps a vertical projection of the pins in the thickness direction of the second substrate.

Optionally, the substrate module further includes a conductive structure disposed in the filling layer, where the driver chip is connected to a pin through at least one of connection lines and conductive vias on the first substrate, the conductive structure, and at least one of connection lines and conductive vias on the second substrate.

Optionally, the conductive structure is an alloy ball.

Optionally, the driver chip includes a first power input leg and a second power input leg, the pins include a first power input pin and a second power input pin, the first power input leg is connected to the first power input pin, and the second power input leg is connected to the second power input pin.

Optionally, the driver chip further includes two ground legs, the pins further include two ground pins, and the two ground legs are connected to the two ground pins in one-to-one correspondence.

Optionally, the two ground pins are connected in series.

Optionally, a copper clad layer is disposed on the side of the second substrate facing away from the first substrate, and the copper clad layer is configured to enhance heat dissipation performance of the second substrate.

Optionally, the filling layer is made of a thermally conductive insulating material.

Embodiments of the present application further provide a method for manufacturing a substrate module. The method includes providing a first substrate on which pad groups and a test terminal are disposed; disposing a driver chip on a side of the first substrate facing away from the pad groups and the test terminal, and connecting the driver chip to the pad groups and the test terminal separately; disposing a second substrate on a side of the driver chip facing away from the first substrate, disposing pins on a side of the second substrate facing away from the first substrate, and connecting the driver chip to the pins; and forming a filling layer between the first substrate and the second substrate, where the filling layer is configured to enclose the driver chip.

Optionally, the first substrate and the second substrate are each provided with connection lines and conductive vias; and that the driver chip is connected to the pins includes disposing a conductive structure between the first substrate and the second substrate so that the driver chip is connected to a pin through at least one of connection lines and conductive vias on the first substrate, the conductive structure, and at least one of connection lines and conductive vias on the second substrate.

Optionally, disposing the conductive structure between the first substrate and the second substrate so that the driver chip is connected to the pin through at least one of the connection lines and the conductive vias on the first substrate, the conductive structure, and at least one of the connection lines and the conductive vias on the second substrate includes: coating a first solder on at least one of the connection lines and the conductive vias on the first substrate; soldering the conductive structure through the first solder onto a connection line or a conductive via on the first substrate; coating a second solder on at least one of the connection lines and the conductive vias on the second substrate; and bonding the second substrate to the first substrate soldered with the conductive structure, and soldering the conductive structure through the second solder onto a connection line or a conductive via on the second substrate.

Optionally, disposing the conductive structure between the first substrate and the second substrate so that the driver chip is connected to the pin through at least one of the connection lines and the conductive vias on the first substrate, the conductive structure, and at least one of the connection lines and the conductive vias on the second substrate includes: disposing the conductive structure at a connection line or a conductive via on the first substrate; disposing a temporary carrier plate on a side of the conductive structure facing away from the first substrate so that the conductive structure is fixed to the first substrate; electroplating a conductive material at a junction between the conductive structure, and the connection line or the conductive via on the first substrate, so that the conductive structure is connected to the connection line or the conductive via on the first substrate; removing the temporary carrier plate, and bonding the second substrate to the first substrate connected with the conductive structure; and electroplating a conductive material at a junction between the conductive structure, and the connection line or the conductive via on the second substrate, so that the conductive structure is connected to at least one of the connection lines and the conductive vias on the second substrate.

Embodiments of the present application further provide a display module. The display module includes light-emitting chips and the substrate module according to the first aspect, where the light-emitting chips are disposed on the pad groups of the first substrate and the light-emitting chips are connected to the pad groups of the first substrate.

Optionally, the light-emitting chips include a first light-emitting chip, a second light-emitting chip, and a third light-emitting chip. The first light-emitting chip, the second light-emitting chip, and the third light-emitting chip emit have different emission colors, and each have a first electrode and a second electrode.

A first electrode of the first light-emitting chip and a first electrode of the second light-emitting chip are connected to a first power input leg of the driver chip through pad groups correspondingly connected to the first light-emitting chip and the second light-emitting chip, and a first electrode of the third light-emitting chip is connected to a second power input leg of the driver chip through a pad group correspondingly connected to the third light-emitting chip. A second electrode of the first light-emitting chip, a second electrode of the second light-emitting chip, and a second electrode of the third light-emitting chip are connected to ground legs of the driver chip through pad groups correspondingly connected to the first light-emitting chip, the second light-emitting chip, and the third light-emitting chip.

Optionally, the light-emitting chips are each a flip chip.

### BRIEF DESCRIPTION OF DRAWINGS

FIG. 1 is a sectional view of a substrate module according to an embodiment of the present application.

FIG. 2 is a top view of a first substrate according to an embodiment of the present application.

FIG. 3 is a bottom view of a first substrate according to an embodiment of the present application.

FIG. 4 is a top view of a second substrate according to an embodiment of the present application.

FIG. 5 is a bottom view of a second substrate according to an embodiment of the present application.

FIG. 6 is a flowchart of a method for manufacturing a substrate module according to an embodiment of the present application.

FIG. 7 is a structural diagram of a display module according to an embodiment of the present application.

### DETAILED DESCRIPTION

The present application is described below in conjunction with drawings and embodiments. It is to be understood that the embodiments described herein are intended to illustrate the present application and not to limit the present application. Additionally, it is to be noted that for ease of description, only part of structures related to the present application are illustrated in the drawings.

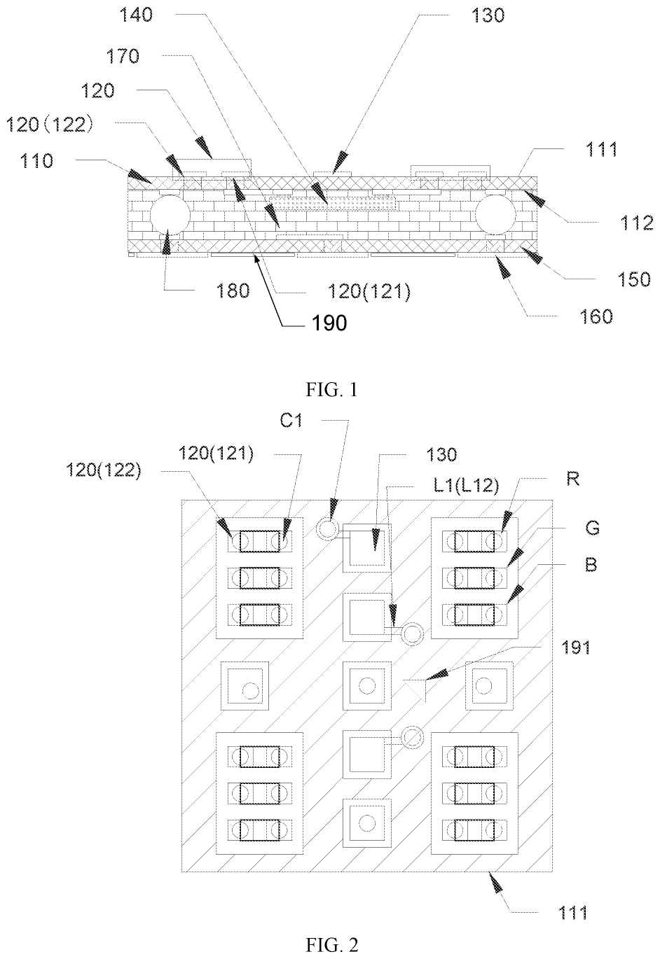

FIG. 1 is a sectional view of a substrate module according to an embodiment of the present application. As shown in FIG. 1, the substrate module includes a first substrate 110, a driver chip 140, a second substrate 150, and a filling layer 170.

Pad groups 120 and test terminals 130 are disposed on the first substrate 110.

The driver chip 140 is disposed on a side of the first substrate 110 facing away from the pad groups 120 and the test terminals 130, and the driver chip 140 is connected to the pad groups 120 and the test terminals 130 separately.

The second substrate 150 is disposed on a side of the driver chip 140 facing away from the first substrate 110, pins 160 are disposed on a side of the second substrate 150 facing away from the first substrate 110, and the driver chip 140 is connected to the pins 160.

The filling layer 170 is disposed between the first substrate 110 and the second substrate 150 and configured to enclose the driver chip 140.

The first substrate 110 and the second substrate 150 may each be a printed circuit board (PCB). The first substrate 110 may include a first surface 111 and a second surface 112, the pad groups 120 and the test terminals 130 may be disposed on the first surface 111, and the driver chip 140 may be disposed on the second surface 112. The driver chip 140 is disposed on the second surface 112 so that the driver chip 140 can be prevented from occupying an area of the first surface 111, and an area of the first substrate 110 for disposing the pad groups 120 can be ensured, thereby increasing a density at which the pad groups 120 are disposed on the first substrate 110. When the substrate module is used for forming a display module, the pad groups 120 are used for connecting light-emitting chips. When the pad groups 120 are at a relatively large density, the density of the light-emitting chips on the display module can be increased, thereby increasing the pixel density of the display module.

The driver chip 140 may include multiple legs. The legs of the driver chip 140 may be connected to external drive signals through the pins 160 on the second substrate 150 or connected to external drive signals through the test terminals 130 on the first substrate 110. The external drive signals drive, through the driver chip 140, the light emission of the light-emitting chips connected to the pad groups 120. When the legs of the driver chip 140 are connected to the external drive signals through the test terminals 130 on the first substrate 110, the external drive signals may be test signals. A test process may occur after the driver chip 140 is encapsulated by the filling layer 170. External test signals are input through the test terminals 130 to test the driver chip 140 and circuits. When a test result is poor, a light-emitting chip corresponding to a pad group 120 at a poor position may be prevented from die bonding in the subsequent die bonding process, thereby reducing the waste of the light-emitting chip and helping to reduce the production cost of the display module. A test process may also occur after the die bonding on the substrate module is completed. The external drive signals are transmitted to the driver chip 140 through the test terminals 130, and the driver chip 140 may drive, according to the external drive signals, the light-emitting chips connected to the pad groups 120 to emit light so that the display module can be detected after the driver chip 140 is integrated into the substrate module to detect a defect of the display module. Thus, a defective product can be eliminated according to test results, and the yield of the display module can be improved. Moreover, in response to a fault during use of the display module, the display module may be provided with detection signals through the test terminals 130, facilitating the determination of a position and cause of the fault of the display module and facilitating the repair of the display module.

When the legs of the driver chip 140 are connected to the external drive signals through the pins 160 on the second substrate 150, the external drive signals may provide normal light emission drive signals to drive the light-emitting chips connected to the pad groups 120, and connection lines between the driver chip 140 and the pins 160 are located in the display module so that when the display module is connected to the external drive signals, a connection difficulty of the display module can be reduced. Moreover, the filling layer 170 is disposed around the driver chip 140 to enclose the driver chip 140 so that the driver chip 140 can be in-built between the first substrate 110 and the second substrate 150 to implement the circuit integration and structural integration of the substrate module, helping to reduce the volume of the substrate module. Furthermore, the substrate module requires only two layers of substrates to implement the integration of the substrate module, reducing the cost of the substrate module. Additionally, constant-current signals may be provided for the driver chip 140 through the pins 160 so that the light-emitting chips connected to the pad groups 120 can be driven at a constant current. Thus, the display module can implement static scanning, a moire phenomenon and a back pressure phenomenon are reduced, and relatively high brightness and reliability of the display module are ensured.

According to the technical solutions of this embodiment, the test terminals are disposed on the first substrate, the test terminals are connected to the driver chip, and the driver chip is connected to the pad groups so that the drive signals can be provided for the driver chip through the test terminals to test the driver chip and circuits. When the test result is poor, the light-emitting chip corresponding to the pad group at the poor position may be prevented from die bonding in the subsequent die bonding process, thereby reducing the waste of the light-emitting chip and helping to reduce the production cost of the display module. Alternatively, after the die bonding, the driver chip drives, according to the drive signals, the light-emitting chips connected to the pad groups to emit light so that the display module is detected after the driver chip is integrated into the substrate module to detect the defect of the display module. Thus, the defective product can be eliminated according to the test results, and the yield of the display module can be improved. Moreover, in response to the fault during use of the display module, the display module may be provided with the detection signals through the test terminals, facilitating the determination of the position and cause of the fault of the display module and facilitating the repair of the display module. Furthermore, the driver chip is encapsulated between the first substrate and the second substrate to implement the circuit integration and structural integration of the display module, helping to reduce the volume of the display module. Meanwhile, the driver chip can be prevented from occupying space on the first substrate, and the density at which the pad groups are disposed on the first substrate can be increased. When the substrate module is used for forming the display module, the pad groups are used for connecting the light-emitting chips. When the pad groups are at a relatively large density, the density of the light-emitting chips on the display module can be increased, thereby increasing the pixel density of the display module and improving the display performance of the display module. Furthermore, the substrate module requires only two layers of substrates to implement the integration of the substrate module, reducing the cost of the substrate module.

Based on the preceding technical solutions, the first substrate 110 and the second substrate 150 are provided with connection lines and conductive vias, and the driver chip 140 is connected to the pad groups 120, the test terminals 130, and the pins 160 separately through the connection lines and the conductive vias.

The pad groups 120 and the test terminals 130 are disposed on one side of the first substrate 110, and the driver chip 140 is disposed on the other side of the first substrate 110. The first substrate 110 is provided with connection lines and conductive vias so that the driver chip 140 can be connected to the pad groups 120 and the test terminals 130 through at least the conductive vias and the connection lines on the first substrate 110. Similarly, the driver chip 140 and the pins 160 are disposed on one side and the other side of the second substrate 150 respectively, and the second substrate 150 is provided with connection lines and conductive vias so that the driver chip 140 can be connected to the pins 160 through at least the conductive vias and the connection lines on the second substrate 150. When the legs of the driver chip 140 are connected to the first substrate 110 through the conductive vias and the connection lines on the first substrate 220, the legs of the driver chip 140 are disposed on a side of the driver chip 140 facing the first substrate 110. When the legs of the driver chip 140 are connected to the pins 160, the legs of the driver chip 140 may be connected to the pins 160 through connection lines and/or conductive vias on the first substrate 110 and through the connection lines and/or the conductive vias on the second substrate 150. The connection lines or the conductive vias of the first substrate 110 may be connected to the connection lines or the conductive vias of the second substrate 150 through processes such as silicon conductive vias or paste soldering.

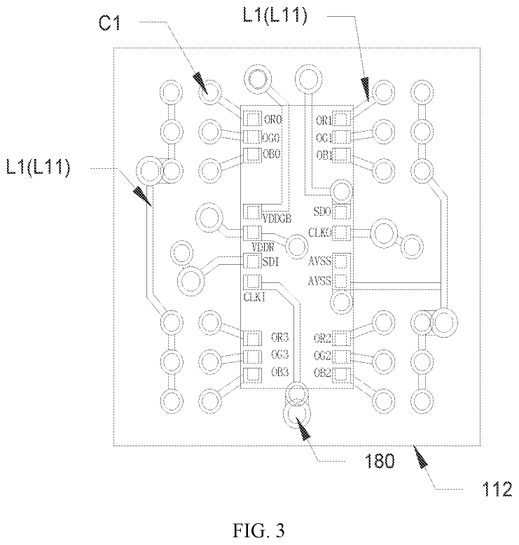

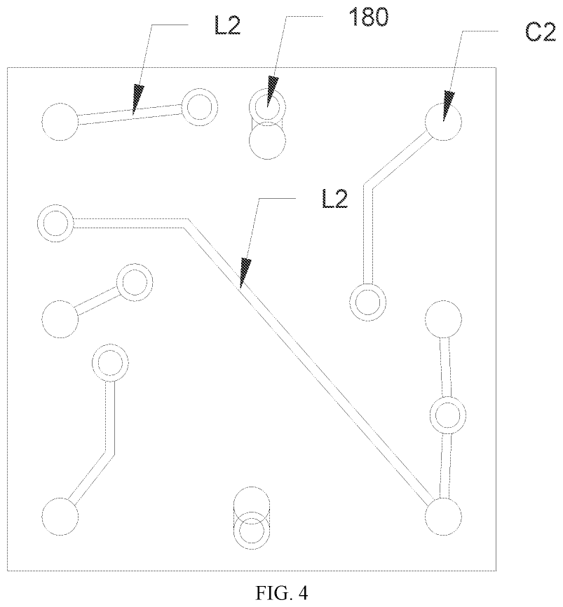

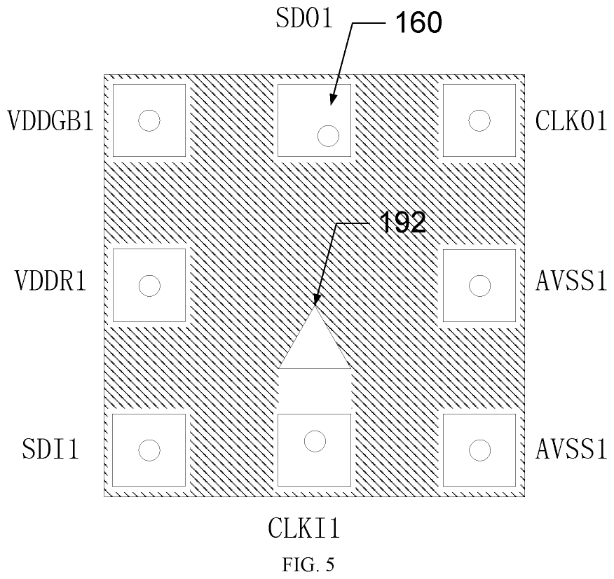

FIG. 2 is a top view of a first substrate according to an embodiment of the present application. FIG. 3 is a bottom view of a first substrate according to an embodiment of the present application. FIG. 4 is a top view of a second substrate according to an embodiment of the present application. FIG. 5 is a bottom view of a second substrate according to an embodiment of the present application. As shown in FIGS. 2 to 5, the first substrate 110 is provided with first conductive vias C1 and first connection lines L1, the second substrate 150 is provided with second conductive vias C2 and second connection lines L2, and each pad group 120 includes a first electrode pad 121 and a second electrode pad 122; and the driver chip 140 is connected to each test terminal 130 and the first electrode pad 121 through a first conductive via C1 and a first connection line L1, the driver chip 140 is connected to second electrode pads 122 through first conductive vias C1, first connection lines L1, and second connection lines L2, and the driver chip 140 is connected to each pin 160 through the first connection line L1 and/or the first conductive via C1 and a second conductive via C2 and/or a second connection line L2.

When the pad group 120 is connected to the light-emitting chip, the first electrode pad 121 and the second electrode pad 122 are connected to a first electrode and a second electrode of the light-emitting chip, respectively. For example, when the first electrode is an anode of the light-emitting chip and the second electrode is a cathode of the light-emitting chip, the first electrode pad 121 is an anode pad and the second electrode pad 122 is a cathode pad. When the first electrode is the cathode of the light-emitting chip and the second electrode is the anode of the light-emitting chip, the first electrode pad 121 is the cathode pad and the second electrode pad 122 is the anode pad. Multiple pad groups 120 may be disposed on the first substrate 110, each pad group 120 is connected to one corresponding light-emitting chip, and multiple light-emitting chips correspondingly connected to the multiple pad groups 120 are connected in common so that the number of solder joints on a circuit board of a customer can be reduced and the structure of the circuit board of the customer can be simplified. For example, as shown in FIGS. 2 and 3, when first electrode pads 121 in the multiple pad groups 120 and the driver chip 140 are disposed on one side and the other side of the first substrate 110 respectively, the driver chip 140 may be directly connected to the first electrode pad 121 through the first conductive via C1 and the first connection line L1. Meanwhile, the second electrode pads 122 in the multiple pad groups 120 may be connected in common through the first connection lines L1 on the first substrate 110 and the second connection lines L2 on the second substrate 150 and then connected to the driver chip 140 through the first conductive vias C1 and the first connection lines L1. When the second electrode pads 122 are connected in common through the first connection lines L1 on the first substrate 110 and the second connection lines L2 on the second substrate 150, the number of pins 160 on the second substrate 150 can be reduced, thereby reducing the number of solder joints on the circuit board of the customer to which the display module is attached and simplifying the structure of the circuit board of the customer. Moreover, a circuit design of the first substrate 110 can be simplified, and a probability that a line is close to an edge of the substrate can be reduced, so as to satisfy a circuit design requirement of the substrate in the subsequent cutting process.

Similarly, the test terminals 130 and the driver chip 140 are disposed on one side and the other side of the first substrate 110 respectively so that the driver chip 140 is connected to the test terminal 130 through the first connection line L1 and the first conductive via C1.

Additionally, the driver chip 140 and the pins 160 are disposed on one side and the other side of the second substrate 150 respectively, and a leg of the driver chip 140 may be connected to a connection point set on the first connection line L1 and/or the first conductive via C1 and then cross-connected to the pin 160 through the second connection line L2 and/or the second conductive via C2.

It is to be noted that a manner in which the driver chip 140 is connected to the pad groups 120, the test terminals 130, and the pins 160 separately, which is provided in FIGS. 2 to 5, is merely an example. In other embodiments, when a setting manner of the first connection lines L1, the first conductive vias C1, the second connection lines L2, and the second conductive vias C2 changes, the manner in which the driver chip 140 is connected to the pad groups 120, the test terminals 130, and the pins 160 separately may change according to the setting manner of the first connection lines L1, the first conductive vias C1, the second connection lines L2, and the second conductive vias C2, which is not limited here.

Still referring to FIGS. 2 to 5, the first connection lines L1 include a first connection subline L11 and a second connection subline L12, the first connection subline L11 is disposed on a side of the first substrate 110 facing the driver chip 140, and the second connection subline L12 is disposed on a side of the first substrate 110 facing away from the driver chip 140; a vertical projection of a part of the first conductive vias C1 in a thickness direction of the first substrate 110 at least partially overlaps a vertical projection of the first electrode pads 121 and the second electrode pads 122 corresponding to the part of the first conductive vias C1 in the thickness direction of the first substrate 110; the driver chip 140 is connected to the first electrode pad 121 through the first conductive via C1 and the first connection subline L11; the driver chip 140 is connected to the second electrode pads 122 through the first conductive vias C1, first connection sublines L11, and the second connection lines L2; and the driver chip 140 is connected to each test terminal 130 through the first conductive via C1 and at least one of the first connection subline L11 and the second connection subline L12.

The driver chip 140 has multiple legs. Some of the legs are connected to the pad groups 120 to provide the drive signals for the pad groups 120. When the pad groups 120 are connected to the light-emitting chips, the light-emitting chips may be driven to emit light. The other part of the legs of the driver chip 140 are connected to the test terminals 130 and the pins 160 so that the driver chip 140 is connected to the outside. In this embodiment, connections to the first electrode pads 121 and the second electrode pads 122 may be used as an example. When the vertical projections of the first conductive via C1 and the first electrode pad 121 in the thickness direction of the first substrate 110 at least partially overlap each other, the first electrode pad 121 may be electrically connected to one end of the first conductive via C1 directly. When vertical projections of the first conductive via C1 and the leg of the driver chip 140 in the thickness direction of the first substrate 110 do not overlap each other, the other end of the first conductive via C1 may be in contact with the first connection subline L11 to be connected to the leg of the driver chip 140, thereby implementing a connection between the first electrode pad 121 and the leg of the driver chip 140. When the vertical projections of the first conductive via C1 and the second electrode pad 122 in the thickness direction of the first substrate 110 at least partially overlap each other, the second electrode pad 122 may be electrically connected to one end of the first conductive via C1 directly. When the vertical projections of the first conductive via C1 and the leg of the driver chip 140 in the thickness direction of the first substrate 110 do not overlap each other, the other end of the first conductive via C1 may be in contact with the first connection subline L11 to be connected to the leg of the driver chip 140, thereby implementing a connection between the second electrode pad 122 and the leg of the driver chip 140. Meanwhile, when the second electrode pads 122 are connected to at least two first connection sublines L11 through multiple first conductive vias C1, the at least two first connection sublines L11 connected to the second electrode pads 122 may be connected through the second connection lines L2 so that multiple second electrode pads 122 are connected in common, thereby reducing lines disposed on the side of the first substrate 110 facing the driver chip 140 and helping to simplify the manufacturing process of the substrate.

Additionally, the legs of the driver chip 140 and the test terminals 130 are disposed on one side and the other side of the first substrate 110 respectively. When vertical projections of the first conductive via C1 and the test terminal 130 on the first substrate 110 at least partially overlap each other, the first conductive via C1 is directly connected to the test terminal 130. When the vertical projections of the first conductive via C1 and the leg of the driver chip 140 on the first substrate 110 do not overlap each other, the first conductive via C1 may be connected to the leg of the driver chip 140 through the first connection subline L11, thereby implementing a connection between the test terminal 130 and the leg of the driver chip 140. When the vertical projections of the first conductive via C1 and the test terminal 130 on the first substrate 110 do not overlap each other, the first conductive via C1 may be connected to the test terminal 130 through the second connection subline L12. When the vertical projections of the first conductive via C1 and the leg of the driver chip 140 on the first substrate 110 do not overlap each other, the first conductive via C1 is connected to the leg of the driver chip 140 through the first connection subline L11, and the first conductive via C1 is connected to the test terminal 130 through the second connection subline L12, thereby implementing a connection between the test terminal 130 and the leg of the driver chip 140. Thus, the drive signals can be provided for the driver chip 140 through the test terminals 130, and the driver chip 140 can drive the light-emitting chips connected to the pad groups 120 to emit light, thereby implementing the detection of the display module.

For example, referring to FIGS. 2 and 3, when the first substrate 110 includes three pad groups 120 and each pad group 120 is used for connecting a light-emitting chip having a different emission color, the driver chip 140 includes three groups of legs connected to electrodes of the light-emitting chips for signal input. One leg in each group of legs is connected to the first electrode pad 121 in one pad group 120, and the other leg in each group of legs is connected to the second electrode pad 122 in the one pad group 120. The number of groups of legs connected to the electrodes of the light-emitting chips is equal to the number of pad groups 120 so that the light-emitting chip connected to each pad group 120 is connected to the driver chip 140. For example, FIGS. 2 and 3 illustratively show four light zones, which are the zeroth light zone, the first light zone, the second light zone, and the third light zone respectively, where each light zone includes three pad groups 120 correspondingly connected to three light-emitting chips which are, for example, a red light-emitting chip, a green light-emitting chip, and a blue light-emitting chip respectively. The driver chip 140 includes three groups of legs connected to electrodes of the light-emitting chips in each light zone, which are connected to the three pad groups 120 in each light zone one to one. For example, a first electrode of a red light-emitting chip R in the zeroth light zone is connected to a leg ORO of the driver chip 140 in the zeroth light zone through one first electrode pad 121 in the three pad groups 120 in the zeroth light zone, a first electrode of a green light-emitting chip G in the zeroth light zone is connected to a leg OGO of the driver chip 140 in the zeroth light zone through another first electrode pad 121 in the three pad groups 120 in the zeroth light zone, and a first electrode of a blue light-emitting chip B in the zeroth light zone is connected to a leg OBO of the driver chip 140 in the zeroth light zone through still another first electrode pad 121 in the three pad groups 120 in the zeroth light zone. In the same manner, first electrodes of a red light-emitting chip R, a green light-emitting chip G, and a blue light-emitting chip B in the first light zone are connected to legs OR1, OG1, and OB1 of the driver chip 140 in the first light zone through first electrode pads 121 in the three pad groups 120 in the first light zone, respectively. First electrodes of a red light-emitting chip R, a green light-emitting chip G, and a blue light-emitting chip B in the second light zone are connected to legs OR2, OG2, and OB2 of the driver chip 140 in the second light zone through first electrode pads 121 in the three pad groups 120 in the second light zone, respectively. First electrodes of a red light-emitting chip R, a green light-emitting chip G, and a blue light-emitting chip B in the third light zone are connected to legs OR3, OG3, and OB3 of the driver chip 140 in the third light zone through first electrode pads 121 in the three pad groups 120 in the third light zone, respectively.

Meanwhile, the legs of the driver chip 140 may further include a first power input leg VDDR, a second power input leg VDDGB, a data input leg SDI, a clock signal input leg CLKI, a data output leg SDO, a clock signal output leg CLKO, and ground legs AVSS. For the second power input leg VDDGB, the data output leg SDO, and the ground legs AVSS, the vertical projections of the corresponding first conductive via C1 and test terminal 130 on the first substrate 110 do not overlap each other so that each of the second power input leg VDDGB, the data output leg SDO, and the ground legs AVSS is connected to the test terminal 130 through the first conductive via C1, the first connection subline L11, and the second connection subline L12. For the first power input leg VDDR, the data input leg SDI, the clock signal input leg CLKI, and the clock signal output leg CLKO, the vertical projections of the corresponding first conductive via C1 and test terminal 130 on the first substrate 110 at least partially overlap each other so that each of the first power input leg VDDR, the data input leg SDI, the clock signal input leg CLKI, and the clock signal output leg CLKO is connected to the test terminal 130 through the first conductive via C1 and the first connection subline L11. The ground legs AVSS enable the driver chip 140 to be grounded.

Still referring to FIGS. 2 to 5, the second connection lines L2 are disposed on a side of the second substrate 150 facing the driver chip 140, and a vertical projection of the second conductive via C2 in a thickness direction of the second substrate 150 at least partially overlaps a vertical projection of the pin 160 in the thickness direction of the second substrate 150.

When the vertical projections of the second conductive via C2 and the pin 160 in the thickness direction of the second substrate 150 at least partially overlap each other, the second conductive via C2 may be directly connected to the pin 160, preventing lines from being disposed on a side of the second substrate 150 facing away from the driver chip 140 and helping to reduce a difficulty in connecting the substrate module to external lines. When the leg of the driver chip 140 is connected to the pin 160, the leg of the driver chip 140 may be connected to the test terminal 130 through the first connection line L1 and the first conductive via C1, and then a connection point is added on at least one of the first connection line L1 and the first conductive via C1 and the connection point is connected to the side of the second substrate 150 facing the driver chip 140 and connected to the pin 160 through at least one of the second connection line L2 and the second conductive via C2 so that the drive signals can be provided for the driver chip 140 through the pins 160, and the driver chip 140 can drive the light-emitting chips connected to the pad groups 120 to emit light, thereby implementing the display of the display module.

For example, referring to FIGS. 2 to 5, when the legs of the driver chip 140 include the first power input leg VDDR, the second power input leg VDDGB, the data input leg SDI, the clock signal input leg CLKI, the data output leg SDO, the clock signal output leg CLKO, and the ground legs AVSS, the pins 160 include a first power input pin VDDR1, a second power input pin VDDGB1, a data input pin SDI1, a clock signal input pin CLKI1, a data output pin SDO1, a clock signal output pin CLKO1, and ground pins AVSS1. Each of the first power input leg VDDR, the second power input leg VDDGB, the clock signal output leg CLKO, the data input leg SDI, and the ground legs AVSS extends through the first connection line L1 and then is connected to the second connection line L2. Vertical projections of the second connection line L2, the second conductive via C2, and the pin 160 in the thickness direction of the second substrate 150 at least partially overlap each other so that the second connection line L2 is connected to the corresponding pin 160 through the second conductive via C2. The data output leg SDO also extends through the first connection line L1 and then is directly connected to the corresponding pin 160 through the second conductive via C2. The clock signal input leg CLKI extends through the first connection line L1 and the first conductive via C1 and then is directly connected to the corresponding pin 160 through the second conductive via C2, where vertical projections of one end of the first connection line L1 and the first conductive via C1 in the thickness direction of the first substrate 110 at least partially overlap each other.

The substrate module further includes conductive structures 180 disposed in the filling layer 170, and the driver chip 140 is connected to the pin 160 through the connection line and/or the conductive via on the first substrate 110, a conductive structure 180, and the connection line and/or the conductive via on the second substrate 150.

When the driver chip 140 is disposed between the first substrate 110 and the second substrate 150, the distance between the first substrate 110 and the second substrate 150 is relatively large along the thickness direction of the first substrate 110. When the leg of the driver chip 140 extends through the first connection line L1, the leg of the driver chip 140 may be connected to the second surface 112 of the first substrate 110. The conductive structure 180 has electrical conductivity. In the thickness direction of the first substrate 110, the conductive structure 180 is separately in contact with the side of the first substrate 110 facing the driver chip 140 and the side of the second substrate 150 facing the driver chip 140. When the driver chip 140 is connected to the pin 160, the leg of the driver chip 140 may be electrically connected to the side of the second substrate 150 facing the driver chip 140 through the conductive structure 180 and then connected to the pin 160 through at least one of the second conductive via C2 and the second connection line L2, so that the second connection line L2 can be prevented from being too thick, implementing a connection to the line on the first substrate 110 and reducing the risk of a short circuit. Meanwhile, the conductive structure 180 has a support function and can prevent the driver chip 140 between the first substrate 110 and the second substrate 150 from being damaged, thereby ensuring the reliability of the substrate module. Additionally, the conductive structure 180 has thermal conductivity and is conducive to ensuring the heat dissipation performance when the first substrate 110 and the second substrate 150 are connected.

For example, referring to FIGS. 1 to 5, each of the first power input leg VDDR, the second power input leg VDDGB, the clock signal output leg CLKO, the data input leg SDI, and the ground legs AVSS of the driver chip 140 extends through the first connection line L1 and vertical projections of one end of the first connection line L1 and the conductive structure 180 in the thickness direction of the first substrate 110 at least partially overlap each other so that the first connection line L1 is connected to the conductive structure 180. Vertical projections of the conductive structure 180 and the second connection line L2 in the thickness direction of the second substrate 150 at least partially overlap each other so that the conductive structure 180 is connected to the second connection line L2. The vertical projections of the second connection line L2, the second conductive via C2, and the pin 160 in the thickness direction of the second substrate 150 at least partially overlap each other so that the second connection line L2 is connected to the corresponding pin 160 through the second conductive via C2. The data output leg SDO also extends through the first connection line L1 and the vertical projections of one end of the first connection line L1 and the conductive structure 180 in the thickness direction of the first substrate 110 at least partially overlap each other so that the first connection line L1 is connected to the conductive structure 180. Vertical projections of the conductive structure 180, the second conductive via C2, and the pin 160 in the thickness direction of the second substrate 150 at least partially overlap each other so that the conductive structure 180 can be directly connected to the corresponding pin 160 through the second conductive via C2. The clock signal input leg CLKI extends through the first connection line L1 and the first conductive via C1, and the vertical projections of one end of the first connection line L1 and the first conductive via C1 in the thickness direction of the first substrate 110 at least partially overlap each other so that the first connection line L1 is connected to the first conductive via C1. Vertical projections of the first conductive via C1 and the conductive structure 180 in the thickness direction of the first substrate 110 at least partially overlap each other so that the first conductive via C1 is connected to the conductive structure 180. The vertical projections of the conductive structure 180, the second conductive via C2, and the pin 160 in the thickness direction of the second substrate 150 at least partially overlap each other so that the conductive structure 180 can be directly connected to the corresponding pin 160 through the second conductive via C2.

The conductive structures 180 may be formed before the filling layer 170. After electrical connections between the first substrate 110 and the second substrate 150 are implemented through the conductive structures 180, the filling layer 170 is provided to enclose the conductive structures 180 and the driver chip 140 to protect the conductive structures 180 and the driver chip 140, thereby implementing the circuit integration and structural integration of the substrate module and helping to reduce the volume of the substrate module.

Optionally, the conductive structure 180 may be an alloy ball, and the alloy ball is in point contact with the first substrate 110 and the second substrate 150. When the alloy ball is soldered to the first substrate 110 and the second substrate 150, a solder can be prevented from accumulating at point contact positions between the alloy ball and the first substrate 110 and the second substrate 150, thereby ensuring that the first substrate 110 and the second substrate 150 are uniform in thickness. Moreover, a probability of cold solder joints can be reduced when the alloy ball is soldered to the first substrate 110 and the second substrate 150.

Still referring to FIGS. 1 to 5, when the first substrate 110 includes multiple pad groups 120, the driver chip 140 includes at least two groups of legs connected to electrodes of light-emitting chips, and each group of legs connected to the electrodes of the light-emitting chip is connected to one pad group 120 to provide a drive signal for the light-emitting chip connected to the one pad group 120, thereby driving the light-emitting chip to emit light. Thus, one driver chip 140 can drive at least two light-emitting chips to emit light, thereby reducing the number of required driver chips 140 based on the determined number of light-emitting chips and reducing the production cost of the display module.

Based on the preceding technical solutions, the driver chip 140 includes the first power input leg VDDR and the second power input leg VDDGB, the pins 160 include the first power input pin VDDR1 and the second power input pin VDDGB1, the first power input leg VDDR is connected to the first power input pin VDDR1, and the second power input leg VDDGB is connected to the second power input pin VDDGB1.

The first power input pin VDDRI is configured to provide a first power supply for the driver chip 140, and the second power input pin VDDGB1 is configured to provide a second power supply for the driver chip 140. When the multiple pad groups 120 are disposed on the first substrate 110 and may be connected to the light-emitting chips having different emission colors, the first power input pin VDDRI and the second power input pin VDDGB1 provide different power supplies for the driver chip 140 so that the driver chip 140 can provide the corresponding power supplies for the light-emitting chips having different emission colors, and the energy consumption of a light-emitting chip with a relatively low power requirement can be reduced. For example, three pad groups 120 are disposed on the first substrate 110, and each pad group 120 is separately connected to the red light-emitting chip, the blue light-emitting chip, or the green light- emitting chip; the red light-emitting chip requires a power supply of 2.8 V, and the green and blue light-emitting chips require a power supply of 3.8 V. In this case, the first power input pin VDDR1may provide a low power supply of, for example, 2.8 V for the red light-emitting chip, and the second power input pin VDDGB1 may provide a high power supply of, for example, 3.8 V for the green and blue light-emitting chips so that the energy consumption of the red light-emitting chip can be reduced.

Based on the preceding technical solutions, the driver chip 140 further includes two ground legs AVSS, the pins 160 further include two ground pins AVSS1, and the two ground legs AVSS are connected to the two ground pins AVSSI one to one.

The two ground legs AVSS may both provide ground terminals for the pad groups 120, that is, provide the ground terminals for the connected light-emitting chips through the pad groups 120 so that the number of light-emitting chips that the driver chip 140 can load can be increased, helping to further reduce the number of required driver chips 140. Additionally, the two ground pins AVSS1 corresponding to the two ground legs AVSS may be symmetrically disposed on the side of the second substrate 150 facing away from the driver chip 140 so that the process of connecting the substrate module to other external structures can be facilitated, helping to save layout space. For example, the two ground pins AVSS1 are connected in series so that the process of connecting the substrate module to external structures on different sides can be further facilitated, thereby further saving the layout space.

Still referring to FIGS. 2 to 5, a first identifier 191 is further provided on the first substrate 110. For example, the first identifier 191 on the first substrate 110 may be disposed on the side of the first substrate 110 facing away from the driver chip 140. A direction in which the light-emitting chips 140 are bonded may be identified through the first identifier 191. Similarly, a second identifier 192 may be provided on the second substrate 150. For example, the second identifier 192 on the second substrate 150 may be disposed on the side of the second substrate 150 facing away from the driver chip 140. The pins 160 on the side of the second substrate 150 facing away from the driver chip 140 can be identified through the second identifier 192 so that the pins are prevented from being wrongly bonded during bonding. Optionally, the first identifier 191 on the first substrate 110 and the second identifier 192 on the second substrate 150 may each be made of a metal. The first identifier 191 on the first substrate 110 may be formed with the pad groups 120 and the test terminals 130 in the same process, and the second identifier 192 on the second substrate 150 may be formed with the pins 160 in the same process.

Based on the preceding multiple technical solutions, a copper clad layer 190 is disposed on the side of the second substrate 150 facing away from the first substrate 110, and the copper clad layer 190 is configured to enhance heat dissipation performance of the side of the second substrate 150 facing away from the first substrate 110.

The copper clad layer 190 is a copper layer formed through copper plating on the side of the second substrate 150 facing away from the first substrate 110. When the copper clad layer 190 is disposed on the side of the second substrate 150 facing away from the first substrate 110, the copper clad layer 190 may be connected to the ground pins AVSS1. The copper clad layer 190 is disposed on the side of the second substrate 150 facing away from the first substrate 110 and the copper clad layer 190 has relatively good heat dissipation performance so that the heat dissipation performance of the substrate module can be improved, internal signals of the substrate module can be provided with additional shielding protection and noise suppression, the amount of corrosive agent used in the production of the substrate module can be reduced, and the warping and deformation of the substrate module caused by uneven stress distribution can be avoided in the soldering process of the substrate module. Additionally, the copper clad layer 190 is made of a metal, an insulating material may be covered on the copper clad layer 190, and the pins are exposed out of the insulating material to avoid a short circuit between patches.

Based on the preceding multiple technical solutions, the filling layer 170 is made of a thermally conductive insulating material.

During the display of the display module, the driver chip 140 easily generates heat. The filling layer 170 is made of the thermally conductive insulating material, making it convenient for the heat generated by the driver chip 140 to be dissipated through the filling layer 170 and helping to ensure the lifetime of the driver chip 140.

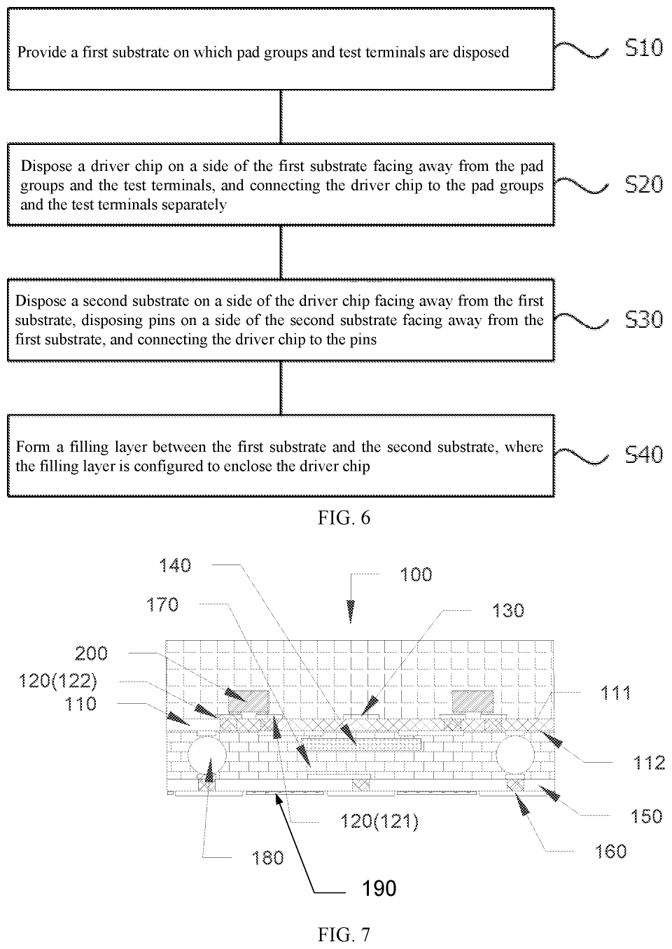

Embodiments of the present application further provide a method for manufacturing a substrate module. The method for manufacturing a substrate module may be used for manufacturing the substrate module of any embodiment of the present application. FIG. 6 is a flowchart of a method for manufacturing a substrate module according to an embodiment of the present application. As shown in FIG. 6, the method includes S10 to S40.

In S10, a first substrate 110 is provided, where pad groups 120 and test terminals 130 are disposed on the first substrate 110.

In S20, a driver chip 140 is disposed on a side of the first substrate 110 facing away from the pad groups 120 and the test terminals 130, and the driver chip 140 is connected to the pad groups 120 and the test terminals 130 separately.

In S30, a second substrate 150 is disposed on a side of the driver chip 140 facing away from the first substrate 110, pins 160 are disposed on a side of the second substrate 150 facing away from the first substrate 110, and the driver chip 140 is connected to the pins 160.

In S40, a filling layer 170 is formed between the first substrate 110 and the second substrate 150, where the filling layer 170 is configured to enclose the driver chip 140.

According to the technical solutions of this embodiment of the present application, the test terminals are disposed on the first substrate, the test terminals are connected to the driver chip, and the driver chip is connected to the pad groups so that drive signals can be provided for the driver chip through the test terminals to test the driver chip and circuits. When a test result is poor, a light-emitting chip corresponding to a pad group at a poor position may be prevented from die bonding in the subsequent die bonding process, thereby reducing the waste of the light-emitting chip and helping to reduce the production cost of a display module. Alternatively, after the die bonding, the driver chip drives, according to drive signals, light-emitting chips connected to the pad groups to emit light so that the display module is detected after the driver chip is integrated into the display module to detect a defect of the display module. Thus, a defective product can be eliminated according to test results, and the yield of the display module can be improved. Moreover, in response to a fault during use of the display module, the display module may be provided with detection signals through the test terminals, facilitating the determination of a position and cause of the fault of the display module and facilitating the repair of the display module. Furthermore, the driver chip is encapsulated between the first substrate and the second substrate to implement the circuit integration and structural integration of the display module, helping to reduce the volume of the display module. Meanwhile, the driver chip can be prevented from occupying space on the first substrate, and the density at which the pad groups are disposed on the first substrate can be increased. When the substrate module is used for forming the display module, the pad groups are used for connecting the light-emitting chips. When the pad groups are at a relatively large density, the density of the light-emitting chips on the display module can be increased, thereby increasing the pixel density of the display module and improving the display performance of the display module. Furthermore, the substrate module requires only two layers of substrates to implement the integration of the substrate module, reducing the cost of the substrate module.

Based on the preceding technical solutions, the first substrate 110 and the second substrate 150 are provided with connection lines and conductive vias, and that the driver chip 140 is connected to the pins 160 includes the following:

Conductive structures 180 are disposed between the first substrate 110 and the second substrate 150 so that the driver chip 140 is connected to each pin 160 through a connection line and/or a conductive via on the first substrate 110, a conductive structure 180, and a connection line and/or a conductive via on the second substrate 150.

When the driver chip 140 is disposed between the first substrate 110 and the second substrate 150, the distance between the first substrate 110 and the second substrate 150 is relatively large along a thickness direction of the first substrate 110. In this case, the conductive structures 180 are disposed between the first substrate 110 and the second substrate 150, and the conductive structure 180 is in contact with the first substrate 110 and the second substrate 150 separately so that connection lines and/or conductive vias on the first substrate 110 and the second substrate 150 can be connected. For example, multiple conductive structures 180 may be disposed, and the conductive structure 180 may be an alloy ball.

After the conductive structures 180 are disposed, when the conductive structure 180 is connected to the connection line on the first substrate 110, a side of the conductive structure 180 facing the first substrate 110 may be in contact with and then electrically connected to the connection line on the first substrate 110. When the conductive structure 180 is connected to the conductive via on the first substrate 110, the side of the conductive structure 180 facing the first substrate 110 may be in contact with and then electrically connected to the conductive via on the first substrate 110.

The driver chip 140 may be connected to the connection line and/or the conductive via on the first substrate 110. After the conductive structure 180 is electrically connected to the connection line and/or the conductive via on the first substrate 110, the second substrate 150 may be bonded against the first substrate 110 so that a side of the conductive structure 180 facing the second substrate 150 is in contact with and then electrically connected to the connection line and/or the conductive via on the second substrate 150. Meanwhile, the connection line and/or the conductive via on the second substrate 150 are connected to the pin 160 so that the driver chip 140 is connected to the pin 160 through the connection line and/or the conductive via on the first substrate 110, the conductive structure 180, and the connection line and/or the conductive via on the second substrate 150.

Based on the preceding technical solutions, that the conductive structures 180 are disposed between the first substrate 110 and the second substrate 150 so that the driver chip 140 is connected to each pin 160 through the connection line and/or the conductive via on the first substrate 110, the conductive structure 180, and the connection line and/or the conductive via on the second substrate 150 includes the following:

A first solder is coated on the connection line and/or the conductive via on the first substrate 110.

The conductive structure 180 is soldered through the first solder onto the connection line or the conductive via on the first substrate 110.

The conductive structure 180 may be electrically connected to the connection line and/or the conductive via on the first substrate 110 by a soldering process. The first solder is coated on the connection line and/or the conductive via on the first substrate 110, and the conductive structure 180 is soldered through the first solder onto the connection line or the conductive via on the first substrate 110.

The conductive structure 180 is soldered to the connection line or the conductive via on the first substrate 110 at the first solder by the soldering process so that the conductive structure 180 is electrically connected to the connection line or the conductive via on the first substrate 100. For example, when the first solder is coated on the connection line on the first substrate 110, the conductive structure 180 may be soldered to the connection line on the first substrate during soldering. When the first solder is coated on the conductive via on the first substrate 110, the conductive structure 180 may be soldered to the conductive via on the first substrate 110 during soldering.

A second solder is coated on the connection line or the conductive via on the second substrate 150.

When the connection line on the second substrate 150 is connected to the conductive structure 180, the second solder may be coated on the connection line on the second substrate 150. When the conductive via on the second substrate 150 is connected to the conductive structure 180, the second solder may be coated on the conductive via on the second substrate 150. The second solder may be the same as or different from the first solder.

The second substrate 150 is bonded to the first substrate 110 soldered with the conductive structure 180, and the conductive structure 180 is soldered through the second solder onto the connection line or the conductive via on the second substrate 150.

When the substrate module is formed, the structures on the first substrate 110 and the structures on the second substrate 150 have a correspondence relationship in position. After the conductive structure 180 is fixedly connected to the connection line and/or the conductive via on the first substrate 110, the first substrate 110 and the second substrate 150 are bonded against each other such that a relative position relationship between the structures on the second substrate 150 and the structures on the first substrate 110 satisfies a requirement of the substrate module. At this time, the connection line and/or the conductive via on the second substrate 150 are in contact with the conductive structure 180.

The conductive structure 180 is soldered to the connection line or the conductive via on the second substrate 150 at the second solder by the soldering process so that the conductive structure 180 is electrically connected to the connection line or the conductive via on the second substrate 150. For example, when the second solder is coated on the connection line on the second substrate 150, the conductive structure 180 may be soldered to the connection line on the second substrate 150 during soldering. When the second solder is coated on the conductive via on the second substrate 150, the conductive structure 180 may be soldered to the conductive via on the second substrate 150 during soldering.

Based on the preceding technical solutions, that the conductive structures 180 are disposed between the first substrate 110 and the second substrate 150 so that the driver chip 140 is connected to each pin 160 through the connection line and/or the conductive via on the first substrate 110, the conductive structure 180, and the connection line and/or the conductive via on the second substrate 150 includes the following:

The conductive structure 180 is disposed at the connection line or the conductive via on the first substrate 110.

When the connection line on the first substrate 110 is connected to the conductive structure 180, the conductive structure 180 may be disposed at the connection line on the first substrate 110 so that the conductive structure 180 is in contact with the connection line on the first substrate 110. When the conductive via on the first substrate 110 is connected to the conductive structure 180, the conductive structure 180 may be disposed at the conductive via on the first substrate 110 so that the conductive structure 180 is in contact with the conductive via on the first substrate 110.

A temporary carrier plate is disposed on a side of the conductive structure 180 facing away from the first substrate 110 so that the conductive structure 180 is fixed to the first substrate 110.

The temporary carrier plate may be a temporary pressing plate. The temporary carrier plate is placed on the side of the conductive structure 180 facing away from the first substrate 110, and the temporary carrier plate applies pressure to the conductive structure 180 so that the conductive structure 180 can be fixed to the first substrate 110.

A conductive material is electroplated at a junction between the conductive structure 180 and the connection line or the conductive via on the first substrate 110 so that the conductive structure 180 is connected to the connection line or the conductive via on the first substrate 110.

The conductive material may be a metal. After the conductive structure 180 is fixed and in contact with the connection line or the conductive via on the first substrate 110, an electroplating process is used to electroplate a contact region between the conductive structure 180 and the connection line or the conductive via on the first substrate 110 so that the conductive material connects the conductive structure 180 to the connection line or the conductive via on the first substrate 110, thereby implementing an electrical connection.

The temporary carrier plate is removed, and the second substrate 150 is bonded to the first substrate 110 connected with the conductive structure 180.

After the conductive structure 180 is connected to the connection line or the conductive via on the first substrate 110, the temporary carrier plate is removed.

The second substrate 150 is bonded to the first substrate 110 connected with the conductive structure 180 such that the relative position relationship between the structures on the second substrate 150 and the structures on the first substrate 110 satisfies the requirement of the substrate module. At this time, the connection line and/or the conductive via on the second substrate 150 are in contact with the conductive structure 180.

A conductive material is electroplated at a junction between the conductive structure 180 and the connection line or the conductive via on the second substrate 150 so that the conductive structure 180 is connected to the connection line and/or the conductive via on the second substrate 150.

The conductive material may also be a metal. The electroplating process is used to electroplate a contact region between the conductive structure 180 and the connection line or the conductive via on the second substrate 150 so that the conductive material connects the conductive structure 180 to the connection line or the conductive via on the second substrate 150. For example, when the connection line on the second substrate 150 is in contact with the conductive structure 180, the electroplating is performed on the contact region between the connection line on the second substrate 150 and the conductive structure 180 so that the conductive material connects the conductive structure 180 to the connection line on the second substrate 150. When the conductive via on the second substrate 150 is in contact with the conductive structure 180, the electroplating is performed on the contact region between the conductive via on the second substrate 150 and the conductive structure 180 so that the conductive material connects the conductive structure 180 to the conductive via on the second substrate 150. When a part of the conductive structure 180 is in contact with the connection line on the second substrate 150 and the other part of the conductive structure 180 is in contact with the conductive via on the second substrate 150, the electroplating process is used to electroplate the contact region between the part of the conductive structure 180 and the connection line on the second substrate 150, and the electroplating process is used to electroplate the contact region between the other part of the conductive structure 180 and the conductive via on the second substrate 150 so that the conductive material connects the part of the conductive structure 180 to the connection line on the second substrate 150 and connects the other part of the conductive structure 180 to the conductive via on the second substrate 150.

Embodiments of the present application further provide a display module. FIG. 7 is a structural diagram of a display module according to an embodiment of the present application. As shown in FIG. 7, the display module includes light-emitting chips 200 and a substrate module 100 of any embodiment of the present application, where the light-emitting chips 200 are disposed on pad groups 120 of a first substrate 110, and the light-emitting chips 200 are connected to the pad groups 120 of the first substrate 110.

Each light-emitting chip 200 may be an LED chip. The light-emitting chips 200 are disposed on the pad groups 120 and connected to a driver chip 140 through the pad groups 120 so that the driver chip 140 in the substrate module 100 can drive the light-emitting chips 200 to emit light.

Additionally, the display module may further include an encapsulation layer configured to mold the light-emitting chips 200 and the substrate module 100 and protect the light-emitting chips 200 and the substrate module 100, thereby increasing the lifetime of the display module.

According to the technical solution of this embodiment, the display module includes the substrate module of any embodiment of the present application, which is not repeated here.

Based on the preceding technical solutions, the light-emitting chips 200 include a first light-emitting chip, a second light-emitting chip, and a third light-emitting chip. The first light-emitting chip, the second light-emitting chip, and the third light-emitting chip have different emission colors, and each have a first electrode and a second electrode; the first electrode of the first light-emitting chip and the first electrode of the second light-emitting chip are connected to a first power input leg of the driver chip 140 through pad groups 120 correspondingly connected to the first light-emitting chip and the second light-emitting chip, and the first electrode of the third light-emitting chip is connected to a second power input leg of the driver chip 140 through a pad group 120 correspondingly connected to the third light-emitting chip; and the second electrode of the first light-emitting chip, the second electrode of the second light-emitting chip, and the second electrode of the third light-emitting chip are connected to ground legs of the driver chip 140 through the pad groups 120 correspondingly connected to the first light-emitting chip, the second light-emitting chip, and the third light-emitting chip.

When the light-emitting chips 200 include the first light-emitting chip, the second light-emitting chip, and the third light-emitting chip having three different emission colors, the first substrate 110 may be provided with three pad groups 120, a first electrode pad 121 in each pad group 120 is separately connected to the first electrode of the first light-emitting chip, second light-emitting chip, or third light-emitting chip, and a second electrode pad 122 in each pad group 120 is separately connected to the second electrode of the first light-emitting chip, second light-emitting chip, or third light-emitting chip. The light-emitting chips 200 having different emission colors may have different power requirements. The first power input leg is connected to pads 121 correspondingly connected to the first electrode of the first light-emitting chip and the first electrode of the second light-emitting chip and configured to provide a first input power supply for the first electrode of the first light-emitting chip and the first electrode of the second light-emitting chip through the corresponding pads 121. The second power input leg is connected to a pad 121 correspondingly connected to the first electrode of the third light-emitting chip and configured to provide a second input power supply for the first electrode of the third light-emitting chip through the corresponding pad group. Thus, the corresponding power supplies are input to the light-emitting chips having different emission colors, and the energy consumption of a light-emitting chip with a relatively low power requirement can be reduced.

For example, the first light-emitting chip may be a blue light-emitting chip B, the second light-emitting chip may be a green light-emitting chip G, and the third light-emitting chip may be a red light-emitting chip R. The red light-emitting chip R requires a power supply of 2.8 V, and the green light-emitting chip G and the blue light-emitting chip B require a power supply of 3.8 V. In this case, the second power input leg may provide the second input power supply for the red light-emitting chip R, and the first power input leg may provide the second input power supply for the green light-emitting chip G and the blue light-emitting chip B so that the energy consumption of the red light-emitting chip R can be reduced. Meanwhile, the second electrodes of the red light-emitting chip R, green light-emitting chip G, and blue light-emitting chip B are connected to the ground legs of the driver chip 140 through pads 122 correspondingly connected to the second electrodes so that the ground legs provide ground terminals for the second electrodes of the red light-emitting chip R, green light-emitting chip G, and blue light-emitting chip B. For example, the driver chip 140 may include two ground legs, and the two ground legs may both provide the ground terminals for the pad groups so that the number of light-emitting chips that the driver chip can load can be increased, helping to further reduce the number of required driver chips.

Based on the preceding multiple technical solutions, the light-emitting chip 200 is a flip chip.

When the light-emitting chip is the flip chip, the process of connecting the light-emitting chips to the first substrate can be simplified, helping to simplify the manufacturing process of the display module.

1. A substrate module, comprising:
a first substrate on which pad groups and a test terminal are disposed;
a driver chip disposed on a side of the first substrate facing away from the pad groups and the test terminal, wherein the driver chip is connected to the pad groups and the test terminal separately;
a second substrate disposed on a side of the driver chip facing away from the first substrate, wherein pins are disposed on a side of the second substrate facing away from the first substrate, and the driver chip is connected to the pins; and
a filling layer disposed between the first substrate and the second substrate and configured to enclose the driver chip.

2. The substrate module according to claim 1, wherein the first substrate and the second substrate are each provided with connection lines and conductive vias, and the driver chip is connected to the pad groups, the test terminal, and the pins separately through connection lines and conductive vias.

3. The substrate module according to claim 2, wherein the first substrate is provided with first conductive vias and first connection lines, the second substrate is provided with second conductive vias and second connection lines, and each of the pad groups comprises a first electrode pad and a second electrode pad;
the driver chip is connected to the test terminal through a first conductive via and a first connection line, and the driver chip is connected to a first electrode pad through a first conductive via and a first connection line;
the driver chip is connected to a second electrode pad through a first conductive via, a first connection line, and a second connection line; and
the driver chip is connected to a pin through at least one of the first connection lines and the first conductive vias, and at least one of the second connection lines and the second conductive vias.

4. The substrate module according to claim 3, wherein the first connection lines comprise a first connection subline and a second connection subline, the first connection subline is disposed on a side of the first substrate facing the driver chip, and the second connection subline is disposed on a side of the first substrate facing away from the driver chip;
a vertical projection of a part of the first conductive vias in a thickness direction of the first substrate at least partially overlaps a vertical projection of first electrode pads and second electrode pads corresponding to the part of the first conductive vias in the thickness direction of the first substrate;
the driver chip is connected to a first electrode pad through a first conductive via and a first connection subline, and the driver chip is connected to a second electrode pad through a first conductive via, a first connection subline, and a second connection line; and
the driver chip is connected to the test terminal through a first conductive via and at least one of the first connection subline and the second connection subline.

5. The substrate module according to claim 3, wherein the second connection lines are disposed on a side of the second substrate facing the driver chip, and a vertical projection of the second conductive vias in a thickness direction of the second substrate at least partially overlaps a vertical projection of the pins in the thickness direction of the second substrate.

6. The substrate module according to claim 2, further comprising a conductive structure disposed in the filling layer, wherein the driver chip is connected to a pin through at least one of connection lines and conductive vias on the first substrate, the conductive structure, and at least one of connection lines and conductive vias on the second substrate.

7. The substrate module according to claim 6, wherein the conductive structure is an alloy ball.

8. The substrate module according to claim 1, wherein the driver chip comprises a first power input leg and a second power input leg, the pins comprise a first power input pin and a second power input pin, the first power input leg is connected to the first power input pin, and the second power input leg is connected to the second power input pin.

9. The substrate module according to claim 8, wherein the driver chip further comprises two ground legs, the pins further comprise two ground pins, and the two ground legs are connected to the two ground pins in one-to-one correspondence.

10. The substrate module according to claim 9, wherein the two ground pins are connected in series.

11. The substrate module according to claim 1, wherein a copper clad layer is disposed on the side of the second substrate facing away from the first substrate, and the copper clad layer is configured to enhance heat dissipation performance of the second substrate.

12. The substrate module according to claim 1, wherein the filling layer is made of a thermally conductive insulating material.

13. A method for manufacturing a substrate module, comprising:
providing a first substrate on which pad groups and a test terminal are disposed;
disposing a driver chip on a side of the first substrate facing away from the pad groups and the test terminal, and connecting the driver chip to the pad groups and the test terminal separately;
disposing a second substrate on a side of the driver chip facing away from the first substrate, disposing pins on a side of the second substrate facing away from the first substrate, and connecting the driver chip to the pins; and
forming a filling layer between the first substrate and the second substrate, wherein the filling layer is configured to enclose the driver chip.

14. The method for manufacturing a substrate module according to claim 13, wherein the first substrate and the second substrate are each provided with connection lines and conductive vias; and connecting the driver chip to the pins comprises:
disposing a conductive structure between the first substrate and the second substrate so that the driver chip is connected to a pin through at least one of connection lines and conductive vias on the first substrate, the conductive structure, and at least one of connection lines and conductive vias on the second substrate.

15. The method for manufacturing a substrate module according to claim 14, wherein disposing the conductive structure between the first substrate and the second substrate so that the driver chip is connected to the pin through at least one of the connection lines and the conductive vias on the first substrate, the conductive structure, and at least one of the connection lines and the conductive vias on the second substrate comprises:
coating a first solder on at least one of the connection lines and the conductive vias on the first substrate;
soldering the conductive structure through the first solder onto a connection line or a conductive via on the first substrate;
coating a second solder on at least one of the connection lines and the conductive vias on the second substrate; and
bonding the second substrate to the first substrate soldered with the conductive structure, and soldering the conductive structure through the second solder onto a connection line or a conductive via on the second substrate.

16. The method for manufacturing a substrate module according to claim 14, wherein disposing the conductive structure between the first substrate and the second substrate so that the driver chip is connected to the pin through at least one of the connection lines and the conductive vias on the first substrate, the conductive structure, and at least one of the connection lines and the conductive vias on the second substrate comprises:
disposing the conductive structure at a connection line or a conductive via on the first substrate;
disposing a temporary carrier plate on a side of the conductive structure facing away from the first substrate so that the conductive structure is fixed to the first substrate;
electroplating a conductive material at a junction between the conductive structure, and the connection line or the conductive via on the first substrate, so that the conductive structure is connected to the connection line or the conductive via on the first substrate;
removing the temporary carrier plate, and bonding the second substrate to the first substrate connected with the conductive structure; and
electroplating a conductive material at a junction between the conductive structure, and the connection line or the conductive via on the second substrate, so that the conductive structure is connected to at least one of the connection lines and the conductive vias on the second substrate.

17. A display module, comprising light-emitting chips and the substrate module according to claim 1, wherein the light-emitting chips are disposed on the pad groups of the first substrate and the light-emitting chips are connected to the pad groups of the first substrate.

18. The display module according to claim 17, wherein the light-emitting chips comprise a first light-emitting chip, a second light-emitting chip, and a third light-emitting chip, wherein the first light-emitting chip, the second light-emitting chip, and the third light-emitting chip have different emission colors, and each have a first electrode and a second electrode;
a first electrode of the first light-emitting chip and a first electrode of the second light-emitting chip are connected to a first power input leg of the driver chip through pad groups correspondingly connected to the first light-emitting chip and the second light-emitting chip, and a first electrode of the third light-emitting chip is connected to a second power input leg of the driver chip through a pad group correspondingly connected to the third light-emitting chip; and
a second electrode of the first light-emitting chip, a second electrode of the second light-emitting chip, and a second electrode of the third light-emitting chip are connected to ground legs of the driver chip through pad groups correspondingly connected to the first light-emitting chip, the second light-emitting chip, and the third light-emitting chip.

19. The display module according to claim 17, wherein the light-emitting chips are each a flip chip.

20. The display module according to claim 17, wherein the first substrate and the second substrate are each provided with connection lines and conductive vias, and the driver chip is connected to the pad groups, the test terminal, and the pins separately through connection lines and conductive vias.
